(19) United States
(12) Patent Application Publication
(10) Pub. No.: US 2026/0072537 A1
(43) Pub. Date: Mar. 12, 2026

(54) FORCE-SENSING USER INPUT MEMBER WITH INTEGRATED TACTILE SWITCH

(71) Applicant: Apple Inc., Cupertino, CA (US)

(72) Inventors: Lei Ma, San Jose, CA (US); Vyom Sharma, Newark, CA (US); Alex M. Lee, Mountain View, CA (US); Daniel M. Winslow, Gilroy, CA (US); Yumeng Liu, Santa Clara, CA (US); Shingo Yoneoka, San Jose, CA (US); Denis G. Chen, San Jose, CA (US); Matthew J. Cheung, Castro Valley, CA (US); Mu-Hua Cheng, Campbell, CA (US); Sherry Cao, San Francisco, CA (US)

(21) Appl. No.: 19/316,405

(22) Filed: Sep. 2, 2025

Related U.S. Application Data
(60) Provisional application No. 63/691,930, filed on Sep. 6, 2024.

(51) Int. Cl. G06F 3/041; G01L 1/22; G06F 3/01; G06F 3/02; H04M 1/02; H05K 1/09; H05K 1/16

(52) U.S. Cl. CPC G06F 3/0414; G01L 1/2262; G06F 3/016; G06F 3/0202; H04M 1/0277; H05K 1/092; H05K 1/167; H05K 2201/0323; H05K 2201/05

(57) ABSTRACT

A strain-sensing device includes a flexible printed circuit and a strain sensor formed on the flexible printed circuit. The flexible printed circuit includes a stacked set of layers. Each layer in the stacked set of layers has a glass transition temperature (Tg) greater than 50 degrees Celsius (50° C.), and each pair of adjacent layers in the stacked set of layers has a Tg greater than 50° C. The stacked set of layers, as a whole, also has a Tg greater than 50° C.

### CROSS-REFERENCE TO RELATED APPLICATIONS

This application claims the benefit under 35 U.S.C. § 119 (e) of U.S. Provisional Patent Application No. 63/691,930, filed Sep. 6, 2024, the contents of which are incorporated herein by reference as if fully disclosed herein.

### FIELD

The described embodiments generally relate to user input members (e.g., buttons, crowns, etc.) for electronic devices and, more particularly, to user input members that are associated with force-sensing or haptic feedback mechanisms.

### BACKGROUND

Many of today's devices include one or more (and typically many) user input members. User input members include buttons, crowns, housing components that are capable of flexing, and so on. Some of these user input members may be associated with force-sensing or haptic feedback mechanisms.

A force-sensing mechanism may be used to determine an amount of force associated with a user input. A device may then evaluate, for example, whether the amount of force associated with the user input is sufficient to convey that the user input is intentional.

A haptic feedback mechanism may be used to acknowledge the receipt of user input (e.g., touch, force, gesture, rotation, or other types of user input). A haptic feedback mechanism may also be used to convey that a device operation has started or finished.

### SUMMARY

Embodiments of the systems, devices, methods, and apparatus described in the present disclosure are directed to electronic devices having user input members associated with force-sensing and haptic feedback mechanisms. In some embodiments, a user input member may be associated with a strain sensor that is capable of detecting a partial press of the user input member (e.g., a half press). The partial press may be achieved when at least a first amount of force is applied to the user input member. The user input member may also be associated with a haptic feedback mechanism (e.g., a piezoelectric material) that provides an acknowledgement of the partial press. Still further, the user input member may be associated with a tactile switch. The tactile switch may provide a haptic output to the user when at least a second amount of force, greater than the first amount of force, is applied to the user input member. The second amount of force may be associated with a full press of the user input member, and may cause a deformable element of the tactile switch to transition from a steady state to a semi-steady state. The tactile switch may provide its haptic output as it transitions from the steady state to the semi-steady state.

In a first aspect, the present disclosure describes an electronic device. The electronic device may include a housing, a bracket disposed interior to the housing and coupled to the housing, a user input member, a tactile switch, a strain sensor, a haptic actuator, and a control circuit. The user input member may be coupled to and movable with respect to the housing. The user input member may have a user input surface exterior to the housing and an actuation surface interior to the housing. The tactile switch may be actuated by movement of the actuation surface toward the bracket. The tactile switch may provide a first haptic output to the user input member when an amount of force applied to the user input surface satisfies an actuation force of the tactile switch. The strain sensor may be laminated to the bracket or to the user input member. The strain sensor may be positioned to experience strain as a force is applied to the user input surface. The haptic actuator may be coupled to the user input member and may provide a second haptic output to the user input member when the haptic actuator is triggered. The control circuit may be configured to receive an output of the strain sensor. The control circuit may trigger the haptic actuator when the output of the strain sensor indicates the amount of force applied to the user input surface satisfies a force threshold that is less than an amount of force required to satisfy the actuation force of the tactile switch.

In a second aspect, the present disclosure describes a strain-sensing device. The strain-sensing device may include a flexible printed circuit, and a strain sensor formed on the flexible printed circuit. The flexible printed circuit may include a stacked set of layers. Each layer in the stacked set of layers may have a glass transition temperature (Tg) greater than 50 degrees Celsius (50° C.) (or greater than a high end temperature of an expected operating temperature range), and each pair of adjacent layers in the stacked set of layers may have a Tg greater than 50° C. (or greater than the high end temperature of the expected operating temperature range).

In a third aspect, the present disclosure describes another strain-sensing device. The strain-sensing device may include a flexible printed circuit and a conductive ink on the flexible printed circuit. The conductive ink may define an array of resistor pixels. The array of resistor pixels may have an array width and an array length. For a resistor pixel in the array of resistor pixels, the resistor pixel may have a pixel width along the array width; a pixel length along the array length; and an edge-to-edge spacing between the resistor pixel and an adjacent resistor pixel, along the array length, that is less than or equal to two times the pixel length. The strain-sensing device may also include a first metal on the flexible printed circuit and defining a set of conductive pads, and a second metal at least partially on the flexible printed circuit and electrically connecting the array of resistor pixels and the set of conductive pads in one of a half Wheatstone bridge or a full Wheatstone bridge.

In addition to the example aspects and embodiments described above, further aspects and embodiments will become apparent by reference to the drawings and by study of the following description.

### BRIEF DESCRIPTION OF THE DRAWINGS

The disclosure will be readily understood by the following detailed description in conjunction with the accompanying drawings, wherein like reference numerals designate like structural elements, and in which:

FIGS. 1A and 1B show an example electronic device;

FIG. 2A shows an example user input assembly, with a user input member of the user input assembly in a first position;

FIG. 2B shows the user input assembly of FIG. 2A, with the user input member of the user input assembly in a second position;

FIG. 2C shows the user input assembly of FIG. 2A, with the user input member of the user input assembly in a third position;

FIG. 2D shows an example placement of additional or alternative strain sensors on the user input assembly of FIGS. 2A-2C;

FIG. 3A shows an example plan view of first strain sensor;

FIG. 3B shows a cross-section of the strain sensor shown in FIG. 3A;

FIG. 4 shows an example plan view of a second strain sensor;

FIG. 5 shows an example elevation of a strain-sensing device including a strain sensor formed on a flexible printed circuit; and

FIG. 6 shows an example electrical block diagram of an electronic device.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following description is not intended to limit the embodiments to one preferred embodiment. To the contrary, it is intended to cover alternatives, modifications, and equivalents as can be included within the spirit and scope of the described embodiments as defined by the appended claims.

In various embodiments, a user input member (e.g., a button, a crown, or a housing component that is capable of flexing) may be associated with one or more or all of a force sensor (e.g., a strain sensor), a haptic feedback mechanism, and a tactile switch. In the case of a pressable user input member, a control circuit associated with the user input member may be able to detect a half press (or other partial press) and a full press of the user input member. Alternatively, the control circuit may detect varying amounts of force that are applied to the user input member. In the case of detecting a half press, the control circuit may trigger the haptic feedback mechanism (e.g., a piezoelectric material) to provide a haptic output to the user input member. The haptic output may serve as an acknowledgment of receipt/detection of the half press as user input. In the case of a full press, the tactile switch may automatically provide a haptic output to the user input member, with the haptic output serving as an acknowledgment of receipt of the full press as user input. Although the force-sensing and haptic feedback mechanisms could be used to receive and acknowledge both the half press and the full press, the use of a tactile switch may provide one or more of: an input detection mechanism and haptic feedback mechanism that do not consume power; an input detection mechanism and haptic feedback mechanism that are operable when an electronic device including the user input member is powered OFF; a purely mechanical haptic output having a different feel than an electronically-triggered haptic output; or a haptic output generated by a lower cost component.

Although the concepts and operating principles described herein are described in terms of a pressable user input member, the concepts and operating principles also apply to rotatable and other user input members (e.g., crowns or knobs), such as user input members that can be rotated against a bias pressure to one of a half rotation (or other partial rotation) or a full rotation.

Some aspects of this description are directed to the structure and function of a user input assembly that includes a user input member. Other aspects of this description are directed to the structure and layout of a strain-sensing device that is capable of detecting an amount of force applied to a user input member. The described structure and layout of the strain-sensing device includes details on how a strain sensor may be structured and laid out, and details on how a flexible printed circuit on which the strain sensor is formed may be structured.

A user input assembly as described herein may be used to provide extended user input functionality. For example, upon detection of a half press, a control circuit of the electronic device may enable a special mode of the electronic device. In a camera context, the special mode may include activation of a touch sensor associated with a user input surface of the user input member. Activation of the touch sensor may enable the user to provide touch input (e.g., touch locations, touch gestures, or touch plus force gestures) that operate a zoom setting, exposure setting, or other feature of a camera. In some cases, the feature that is adjusted in response to the touch input may be dependent on the state of a graphical user interface (GUI) displayed on a display of the electronic device, or dependent on a user's configuration of the user input assembly. Upon detection of a full press, the control circuit may perform another camera function, such as operating the shutter of the camera.

A user input assembly as described herein may also be used in non-camera contexts, such as to change a volume, change GUI screens, and so on.

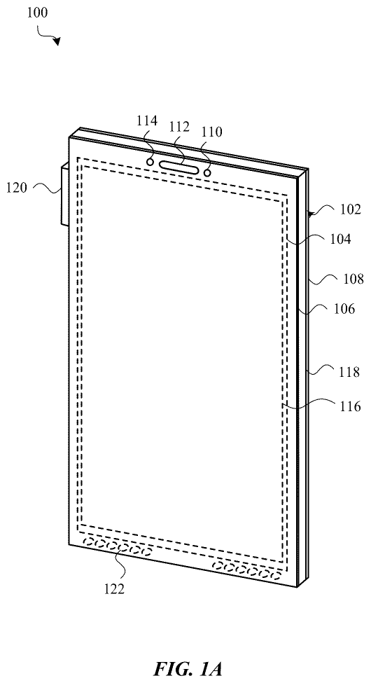

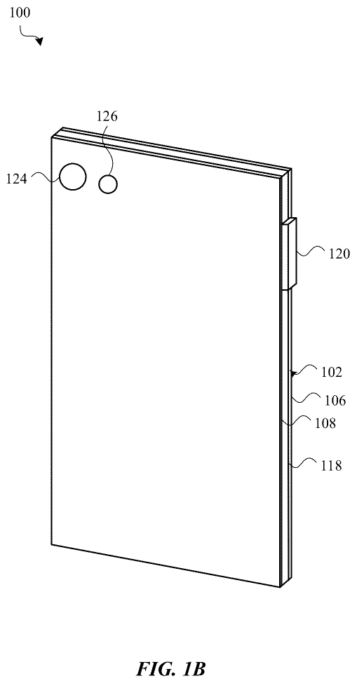

These and other systems, devices, methods, and apparatus are described with reference to FIGS. 1A-6. However, those skilled in the art will readily appreciate that the detailed description given herein with respect to these figures is for explanatory purposes only and should not be construed as limiting.

Directional terminology, such as “top”, “bottom”, “upper”, “lower”, “front”, “back”, “over”, “under”, “above”, “below”, “left”, “right”, etc. is used with reference to the orientation of some of the components in some of the figures described below. Because components in various embodiments can be positioned in a number of different orientations, directional terminology is used for purposes of illustration and is not always limiting. The directional terminology is intended to be construed broadly, and therefore should not be interpreted to preclude components being oriented in different ways. Also, as used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

FIGS. 1A and 1B show an example electronic device 100 that includes various user input components and sensors. In some embodiments, the device 100 may be configured as a mobile phone (e.g., a smartphone) or tablet computer. However, the device's dimensions and form factor are arbitrarily chosen, and the device 100 can alternatively be configured as any portable electronic device including, for example, a portable computer or laptop computer, portable music player, wearable device (e.g., one or more of a watch, health or fitness monitor, earbud, headset, goggles, pair of glasses, and so on), portable terminal, vehicle navigation system, robot navigation system, gaming system, gaming control circuit, gaming accessory, augmented reality (AR) device, virtual reality (VR) device, mixed reality (MR) device, or other portable or mobile device. The device 100 can also be configured as a wearable device or, alternatively, a device that is semi-permanently located (or installed) at a single location (e.g., a door lock, thermostat, refrigerator, or other appliance). FIG. 1A shows a front isometric view of the device 100, and FIG. 1B shows a rear isometric view of the device 100. The device 100 may include a housing 102 that at least partially surrounds a display 104. The housing 102 may include or support a front cover 106 or a rear cover 108. The front cover 106 may be positioned over the display 104 and may provide a window through which the display 104 (including images displayed thereon) may be viewed by a user. In some embodiments, the display 104 may be attached to (or abut) the housing 102 and/or the front cover 106.

The display 104 may include one or more light-emitting elements or pixels, and in some cases may be a light-emitting diode (LED) display, an organic LED (OLED) display, a liquid crystal display (LCD), an electroluminescent (EL) display, a laser projector, or another type of electronic display. In some embodiments, the display 104, the front cover 106, or a stack including the display 104 and/or front cover 106 may include, or be associated with, one or more touch and/or force sensors that are configured to detect a touch and/or a force applied to a surface of the front cover 106.

The various components of the housing 102 may be formed from the same or different materials. For example, a sidewall 118 of the housing 102 may be formed using one or more metals (e.g., stainless steel), polymers (e.g., plastics), ceramics, or composites (e.g., carbon fiber). In some cases, the sidewall 118 may be a multi-segment sidewall including a set of antennas. The antennas may form structural components of the sidewall 118. The antennas may be structurally coupled (to one another or to other components) and electrically isolated (from each other or from other components) by one or more non-conductive segments of the sidewall 118. The front cover 106 may be formed, for example, using one or more of glass, a crystal (e.g., sapphire), or a transparent polymer (e.g., plastic) that enables a user to view the display 104 through the front cover 106. In some cases, a portion of the front cover 106 (e.g., a perimeter portion of the front cover 106) may be coated with an opaque ink to obscure components included within the housing 102. The rear cover 108 may be formed using the same material(s) that are used to form the sidewall 118 or the front cover 106, or a different material or materials. In some cases, the rear cover 108 may be part of a monolithic element that also forms the sidewall 118 (or in cases where the sidewall 118 is a multi-segment sidewall, those portions of the sidewall 118 that are conductive or, alternatively, those portions of the sidewall 118 that are non-conductive). In still other embodiments, all of the exterior components of the housing 102 may be formed from a transparent material, and components within the device 100 may or may not be obscured by an opaque ink or opaque structure within the housing 102.

The front cover 106 may be mounted to the sidewall 118 to cover an opening defined by the sidewall 118 (i.e., an opening into an interior volume in which various electronic components of the device 100, including the display 104, may be positioned). The front cover 106 may be mounted to the sidewall 118 using fasteners, adhesives, seals, gaskets, or other components.

A display stack or device stack (hereafter referred to as a “stack”) including the display 104 (and in some cases the front cover 106) may be attached (or abutted) to an interior surface of the front cover 106 and extend into the interior volume of the device 100. In some cases, the stack may also include a touch sensor (e.g., a grid of capacitive, resistive, strain-based, ultrasonic, or other type of touch sensing elements), or other layers of optical, mechanical, electrical, or other types of components. In some cases, the touch sensor (or part of a touch sensor system) may be configured to detect a touch applied to an outer surface of the front cover 106 (e.g., to a display surface of the device 100).

The stack may also include one or an array of sensors 116, with the sensors positioned in front of or behind, or interspersed with, the light-emitting elements of the display 104. In some cases, an array of sensors 116 may extend across an area equal in size to the area of the display 104. Alternatively, the array of sensors 116 may extend across an area that is smaller than or greater than the area of the display 104 or be positioned entirely adjacent the display 104. Although the array of sensors 116 is shown to have a rectangular boundary, the array could alternatively have a boundary with a different shape, including, for example, an irregular shape. The array of sensors 116 may be variously configured as an ambient light sensor, a health sensor (e.g., age sensor), a touch sensor, a proximity sensor, a biometric sensor (e.g., a fingerprint sensor or facial recognition sensor), a camera, a depth sensor, an air quality sensor, and so on. The array of sensors 116 may also or alternatively function as a proximity sensor, for determining whether an object (e.g., a finger, face, or stylus) is proximate to the front cover 106. In some embodiments, the array of sensors 116 may provide the touch sensing capability (i.e., touch sensor) of the stack.

In some cases, a force sensor (or part of a force sensor system) may be positioned within the interior volume below and/or to the side of the display 104 (and in some cases within the stack). The force sensor (or force sensor system) may be triggered in response to the touch sensor (or touch sensor system) detecting one or more touches on the front cover 106 (or indicating a location or locations of one or more touches on the front cover 106) and may determine an amount of force associated with each touch, or an amount of force associated with the collection of touches as a whole. Alternatively, the touch sensor (or touch sensor system) may be triggered in response to the force sensor (or force sensor system) detecting a force applied to the front cover 106. In some embodiments, force information may be derived from the touch sensor (or touch sensor system), or touch information may be derived from the force sensor (or force sensor system).

As shown primarily in FIG. 1A, the device 100 may include various other components. For example, the front of the device 100 may include one or more front-facing cameras 110 (including one or more image sensors), speakers 112, microphones, or other components 114 (e.g., audio, imaging, and/or sensing components) that are configured to transmit or receive signals to/from the device 100. In some cases, a front-facing camera 110, alone or in combination with other sensors, may be configured to operate as a bio-authentication or facial recognition sensor. Additionally, or alternatively, the array of sensors 116 may be configured to operate as a front-facing camera 110, a bio-authentication sensor, or a facial recognition sensor.

The device 100 may also include buttons or other input devices positioned along the sidewall 118 and/or on a rear surface of the device 100. For example, a multipurpose button 120 may be positioned along the sidewall 118, and in some cases may extend through an aperture in the sidewall 118. The sidewall 118 may include one or more ports 122 that allow air, but not liquids, to flow into and out of the device 100. In some embodiments, one or more sensors may be positioned in or near the port(s) 122. For example, an ambient pressure sensor, ambient temperature sensor, internal/external differential pressure sensor, gas sensor, particulate matter concentration sensor, or air quality sensor may be positioned in or near a port 122.

In some embodiments, the rear surface of the device 100 may include a rear-facing camera 124. A flash or light source 126 may also be positioned along the rear of the device 100 (e.g., near the rear-facing camera). In some cases, the rear surface of the device 100 may include multiple rear-facing cameras.

In some cases, the array of sensors 116, the front-facing camera 110, the rear-facing camera 124, and/or other sensors positioned on the front, back, or sides of the device 100 may emit or transmit signals through the housing 102 (including the front cover 106, rear cover 108, or sidewall 118) and/or receive signals or sense conditions through the housing 102. For example, in some embodiments, one or more such sensors may include a number of electromagnetic radiation emitters (e.g., visible light and/or IR emitters) and/or a number of electromagnetic radiation detectors (e.g., visible light and/or IR detectors, such as any of the electromagnetic radiation detectors described herein).

The device 100 may include circuitry (e.g., a processor and/or other components) configured to determine or extract, at least partly in response to signals received directly or indirectly from one or more of the device's sensors, the receipt of user input, biological parameters of the device's user, a status of the device 100, parameters of an environment of the device 100 (e.g., air quality), or a composition of a target or object, for example. In some embodiments, the circuitry may be configured to convey the determined or extracted parameters or statuses via an output device of the device 100. For example, the circuitry may cause the indication(s) to be displayed on the display 104, indicated via audio or haptic outputs, transmitted via a wireless communications interface or other communications interface, and so on. The circuitry may also or alternatively maintain or alter one or more settings, functions, or aspects of the device 100, including, in some cases, what is displayed on the display 104.

In some embodiments, the button 120 may be associated with a strain sensor (or other type of force sensor) that is capable of determining an amount of force applied to the button 120. The amount of force may be evaluated by the device 100 to determine, for example, whether a user has made a half press of the button 120, a full press of the button 120, a double tap of the button 120, etc. In some embodiments, the button 120 may additionally, or alternatively, be associated with a touch sensor. The touch sensor may determine a location or change in location of a user's touch on the button 120. In some embodiments, the touch sensor may be enabled (or its output may be evaluated) subsequent to a user making a half press of the button 120. The half press may cause the device 100 to enter a special mode in which the touch sensor associated with the button (e.g., a touch sensor capable of detecting touch input on an exterior surface of the button 120) is enabled.

The button 120 may also be associated with a tactile switch. The tactile switch may provide a haptic output to the button when a user fully presses the button.

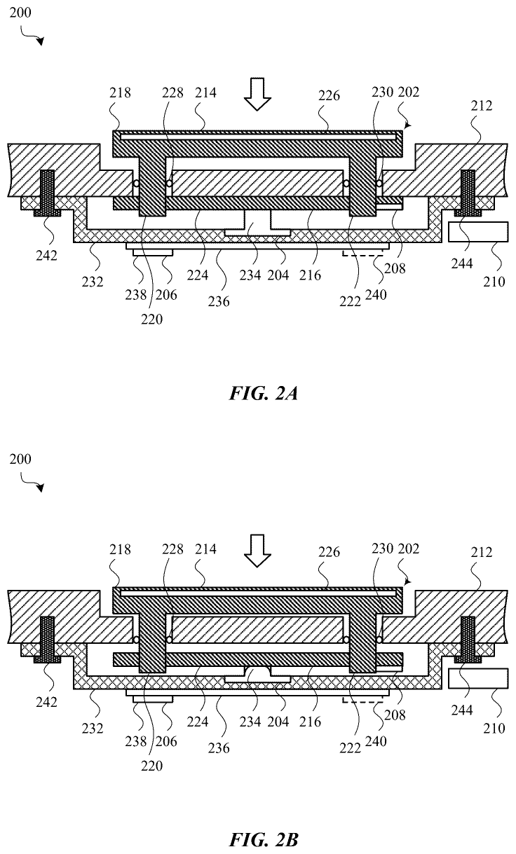

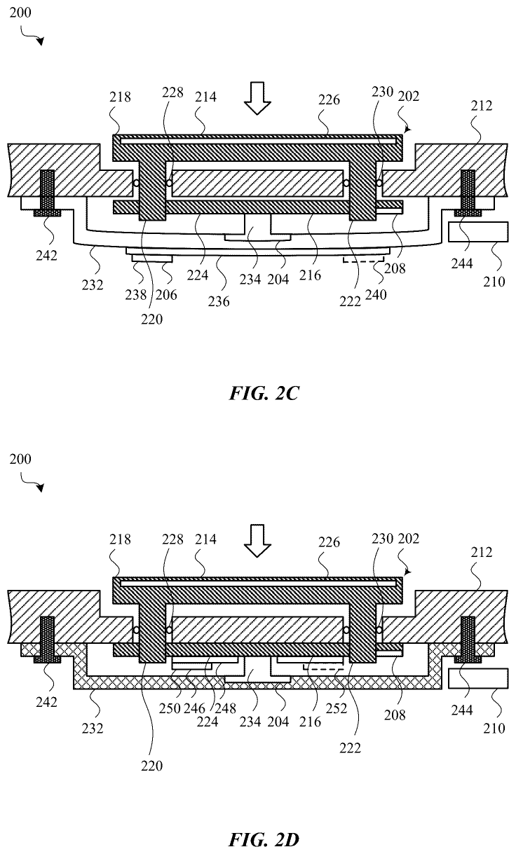

FIGS. 2A, 2B, and 2C show an example user input assembly 200 having a user input member 202. FIG. 2A shows the user input assembly with the user input member 202 in a first position. FIG. 2B shows the user input assembly 200 with the user input member 202 in a second position. FIG. 2C shows the user input assembly 200 with the user input member 202 in a third position. The user input assembly 200 may be used, for example, as the button disposed on the side of the electronic device shown in FIGS. 1A and 1B.

The user input assembly 200 may include, for example, the user input member 202, a tactile switch 204, a strain sensor (or other type of force sensor) 206, a haptic actuator 208, and a control circuit 210. The user input member 202 may be coupled (mechanically coupled) to a housing 212 of an electronic device, and may be movable with respect to the housing 212. The user input member 202 may have a user input surface 214 that is exterior to the housing 212, and an actuation surface 216 that is interior to the housing 212. In some embodiments, the user input member 202 may take the form of a user-pressable button that presents on the exterior of an electronic device.

The user input member 202 may be biased to a first position, in which the user input member 202 is shifted farthest outward from the housing 212 (see FIG. 2A). As a user presses on the user input surface 214, the user input member 202 may move toward the housing 212. As the user applies a greater amount of force to the user input surface 214, the user input member 202 may move to the position illustrated in FIG. 2C, and then to the position illustrated in FIG. 2B.

By way of example, the user input member 202 is shown to include a first component 218 that provides the user input surface 214 and a pair of shafts 220, 222 that are coupled to the user input surface 214 and extend through the housing 212, and a second component 224 that is clipped, welded, or otherwise attached to the first component 218 (e.g., attached to the shafts 220, 222). The user input member 202 may also include other components, such as a touch sensor 226 and/or one or more other sensors. In some embodiments, the touch sensor 226 may be formed on a flexible printed circuit having a pigtail that extends through a hollow shaft 220. The pigtail may carry signal or ground wires that can be connected to a control circuit or ground interior to the housing 212. Alternatively, the user input member 202 may be formed as a single component, or any number of assembled components.

Optionally, a pair of seals (e.g., O-rings 228, 230) may encircle the shafts 220, 222 and provide a seal between the shafts 220, 222 and the housing 212.

In alternative configurations of the user input member 202, the user input member 202 may only have a single shaft or element that extends through the housing 212. The user input member 202 may also have more than two shafts 220, 222. In alternative configurations of the user input member 202, the components of the user input member 202 may have different shapes, or may be positioned in different ways with respect to the housing 212. For example, the user input surface 214 may be rectangular, oval, or otherwise-shaped, and may sit proud of, flush, or within the housing 212.

A bracket 232 may be disposed interior to the housing 212 and coupled (mechanically coupled) to the housing 212. The bracket 232 may in some cases have a width that is wider than the width of the user input member 202, but it need not. The bracket 232 may be attached to the housing 212 in various ways, and by way of example is shown attached to the housing 212 by means of a pair of screws 242, 244. Although the bracket 232 is shown to be symmetrical about the user input member 202, it need not be.

At least a portion of the tactile switch 204 may extend between the bracket 232 and the actuation surface 216 of the user input assembly 200. By way of example, the tactile switch 204 is shown mounted to the bracket 232 (e.g., using an adhesive). Alternatively, the tactile switch may be mounted to the actuation surface 216 (or suspended between the bracket 232 and the actuation surface 216). The tactile switch 204 may be actuated by movement of the actuation surface 216 toward the bracket 232. The tactile switch 204 may provide a first haptic output to the user input member 202 when an amount of force applied to the user input surface 214 satisfies an actuation force of the tactile switch 204. The actuation force is an amount of force at which a deformable element of the tactile switch, such as a collapsible dome or buckling spring, switches from a steady state to a semi-steady state. For example, if the tactile switch 204 is a collapsible dome switch, the actuation force would be an amount of force that causes the collapsible dome (e.g., a rubber dome) to collapse. Removal of the actuation force would allow the collapsible dome to pop back to its steady state. By way of example, FIGS. 2A-2C show a collapsible dome type tactile switch 204, with FIG. 2A showing the collapsible dome 234 in its steady state, FIG. 2B showing the collapsible dome 234 in its semi-steady (or collapsed) state, and FIG. 2C showing the collapsible dome 234 in an intermediate state as a result of a partial depression of the user input member 202 by a user.

The strain sensor 206 may be directly or indirectly laminated to the bracket 232. In some embodiments, and as shown, the strain sensor 206 may be printed or otherwise formed on a flexible printed circuit 236, and the flexible printed circuit 236 may be laminated to the bracket 232. Alternatively, the strain sensor 206 may be provided in a module that is attached to the bracket 232. Regardless of how the strain sensor 206 is attached to the bracket 232, the strain sensor 206 may be positioned to experience strain as a force is applied to the user input surface 214.

In some embodiments, the strain sensor 206 may include a single strain sensing pixel 238 that is positioned to sense strain at a singular location on the bracket 232. In other embodiments, the strain sensor 206 may include at least a first strain sensing pixel 238 and a second strain sensing pixel 240, with the first and second strain sensing pixels 238, 240 being positioned to sense strain at different locations on the bracket 232. In this manner, the different strain sensing pixels may be used to estimate a force centroid of force applied to the user input member 202, which force centroid may be used to compensate for where a force is applied to the user input member 202 or determine where a force has been applied to the user input member 202. Although one or more strain sensing pixels 238, 240 are shown on a side of the bracket 232 that is opposite to a side of the bracket 232 on which the user input member 202 is disposed, one or more strain sensing pixels may also or alternatively be disposed on the side of the bracket 232 that faces the user input member 202; or within a cavity formed in the bracket 232. In some cases, one or more strain sensing pixels may be positioned on a thinner portion (or portions) of the bracket 232, which thinner portion(s) are more susceptible to experiencing strain of the bracket 232.

By way of example, the haptic actuator 208 is shown coupled (mechanically coupled) to the user input member 202. However, the haptic actuator 208 may in some cases be attached to the housing 212, the bracket 232, or another component that is capable of providing or propagating a haptic output (a second haptic output) to a user in contact with the user input surface 214. The haptic actuator 208 may variously include a piezoelectric material, an eccentric motor, an acoustic coil, or another type of haptic actuator. In some embodiments, the haptic actuator 208 may not be included.

The control circuit 210 may include, for example, a processor and/or discrete circuits. The control circuit 210 may be configured to receive an output of the strain sensor 206, and trigger the haptic actuator 208 (i.e., trigger the haptic actuator 208 to provide the second haptic output) when the output of the strain sensor 206 indicates the amount of force applied to the user input surface 214 satisfies a force threshold. The force threshold may be a threshold that is less than an amount of force required to satisfy the actuation force of the tactile switch 204.

In use, a user may apply a force to the user input member 202. When the output of the strain sensor 206 is interpreted by the control circuit 210 as indicting that an amount of force applied to the user input member 202 by the user corresponds to a “half press” of the user input member 202, and if the haptic actuator 208 is provided, the control circuit 210 may trigger the haptic actuator 208 to provide the second haptic output to the user input member 202 (as an acknowledgement that the user's half press has been received). The control circuit 210 may also provide a signal (e.g., to an additional control circuit or processor of the electronic device, or to an operating system of the electronic device, or to the touch sensor 226), which signal indicates that the user has provided the half press. The half press may trigger a special mode of the electronic device. In some embodiments, the special mode may enable the touch sensor 226 to receive touch input (e.g., gestures) provided by the user. In some embodiments, the touch input may be used to adjust a zoom setting, exposure setting, or other feature of a camera. In some embodiments, the touch input may be used for other purposes. FIG. 2C shows the user input assembly 200 at the moment a half press is registered. The bending (strain) in the bracket 232 has been accentuated for affect. In an actual device, the bending may or may not be visually perceptible.

As an amount of force applied by a user to the user input surface 214 increases, the amount of force may satisfy the actuation force of the tactile switch 204, and the deformable element (e.g., the collapsible dome 234) of the tactile switch 204 may provide the first haptic output to the user input member 202. At or about the time that the actuation force is satisfied, the tactile switch 204 may generate a signal indicating that the user has provided a “full press” of the user input member 202. In some embodiments, the full press may operate the shutter of a camera. The full press may alternatively be interpreted in different ways. In some cases, the full press may be interpreted based on a user configuration of the user input member 202, or based on a context of a graphical user interface (GUI) displayed on an electronic device. FIG. 2B shows the user input assembly 200 at the moment a full press is registered.

FIG. 2D shows an example placement of additional or alternative strain sensors on the user input assembly of FIGS. 2A-2C. For example, a strain sensor 246 may be mounted to the user input member 202.

The strain sensor 246 may be directly or indirectly laminated to the user input member 202. In some embodiments, and as shown, the strain sensor 246 may be printed or otherwise formed on a flexible printed circuit 248, and the flexible printed circuit 248 may be laminated to the user input member 202. Alternatively, the strain sensor 246 may be provided in a module that is attached to the user input member 202. Regardless of how the strain sensor 246 is attached to the user input member 202, the strain sensor 246 may be positioned to experience strain as a force is applied to the user input surface 214.

In some embodiments, the strain sensor 246 may include a single strain sensing pixel 250 that is positioned to sense strain at a singular location on the user input member 202. In other embodiments, the strain sensor 246 may include at least a first strain sensing pixel 250 and a second strain sensing pixel 252, with the first and second strain sensing pixels 250, 252 being positioned to sense strain at different locations on the user input member 202. In this manner, the different strain sensing pixels may be used, for example, to estimate a force centroid of force applied to the user input member 202. Although one or more strain sensing pixels 250, 252 are shown on the actuation surface 216 of the user input member 202, one or more strain sensing pixels may also or alternatively be disposed on a different surface of the user input member 202, such as on a surface of the user input member 202 that is opposite to the actuation surface 216, or on or under the user input surface 214. In some cases, one or more strain sensing pixels may be positioned on a thinner portion (or portions) of the user input member 202, which thinner portion(s) are more susceptible to experiencing strain of the user input member 202.

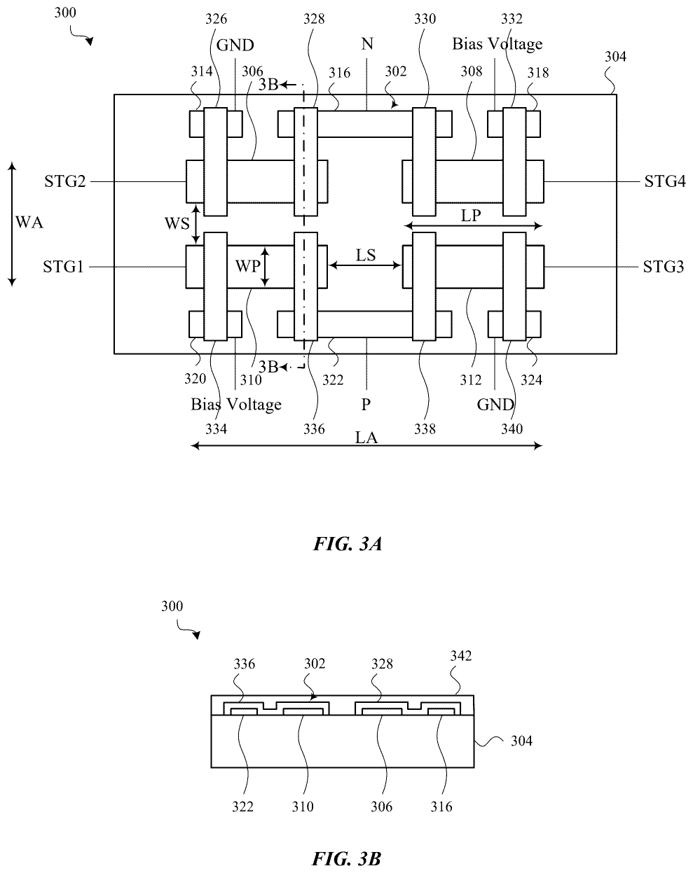

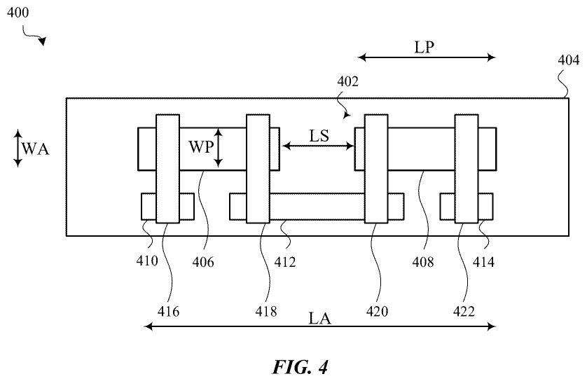

FIG. 3A shows an example plan view of a strain-sensing device 300 including a first strain sensor 302. FIG. 3B shows a cross-section of the strain-sensing device 300. The strain sensor 302 is an example of any of the strain sensing pixels described with reference to FIGS. 2A-2D.

The strain sensor 302 may be formed on a flexible printed circuit 304 or other substrate. The strain sensor 302 may include a conductive ink (e.g., a carbon fiber ink) that is printed on the flexible printed circuit 304. The conductive ink may have a resistance and define an array of resistor pixels 306, 308, 310, 312 having an array width (WA) and an array length (LA). By way of example, the strain sensor 302 has four resistor pixels 306, 308, 310, 312, which resistor pixels 306, 308, 310, 312 may be electrically coupled to one another in a full Wheatstone bridge.

Each resistor pixel 306, 308, 310, 312 is shown to have the same dimensions and be positioned in a different location of a grid formation. In alternative embodiments, resistor pixels may have different sizes or different placements. When the resistor pixels 306, 308, 310, 312 have the same dimensions, each resistor pixel 306, 308, 310, 312 may have a pixel width (WP) along the array width (WA) and a pixel length (LP) along the array length (LA). Along the array width, the resistor pixels 306, 308, 310, 312 may have a first edge-to-edge spacing (WS; between a resistor pixel and an adjacent resistor pixel), and along the array length, the resistor pixels 306, 308, 310, 312 may have a second edge-to-edge spacing (LS; between a resistor pixel and an adjacent resistor pixel).

Because temperature can change the resistance of one or more resistor pixels, and to reduce the effects of temperature on strain sensing, the resistor pixels 306, 308, 310, 312 may be positioned relatively closer to one another (i.e., so that the resistor pixels 306, 308, 310, 312 experience similar temperature changes and one or more resistor pixels do not become much warmer or cooler than the other resistor pixels). However, positioning the resistor pixels 306, 308, 310, 312 too close to each other can reduce a strain sensor's sensitivity to strain. In some embodiments, the first edge-to-edge spacing may be less than or equal to two times the pixel width and/or the second edge-to-edge spacing may be less than or equal to two times the pixel length, to minimize the impact of temperature differentials between adjacent resistor pixels. In some embodiments, the first edge-to-edge spacing may be between one and two times the pixel width and/or the second edge-to-edge spacing may be between one and two times the pixel length. In some embodiments, the first edge-to-edge spacing may be less than or equal to the pixel width and/or the second edge-to-edge spacing may be less than or equal to the pixel length.

A first metal (e.g., copper) may be printed on the flexible printed circuit 304 and define a set of conductive pads 314, 316, 318, 320, 322, 324. The conductive pads may be positioned close to the resistor pixels 306, 308, 310, 312 (e.g., within two times the pixel width, or between one and two times the pixel width, or within one pixel width), so that they tend to respond to temperature changes similarly to the resistor pixels 306, 308, 310, 312. Although copper is a good thermal conductor, the first metal could alternatively be silver, gold, aluminum, or another type of metal. Some of the conductive pads 316, 322 may be shared by two of the resistor pixels (e.g., 306 and 308, or 310 and 312) and help distribute temperature changes across different resistor pixels 306, 308, 310, 312. In some embodiments, and as shown, the conductive pads 316 and 322 may each overlap the lengths of two adjacent resistor pixels (e.g., 306 and 308, or 310 and 312). The overlap may amount to up to 25% of the pixel length (or up to 50%, or up to 75%, or more).

A second metal (e.g., silver) may be printed at least partially on the flexible printed circuit 304 (and at least partially on the resistor pixels 306, 308, 310, 312 and conductive pads 314, 316, 318, 320, 322, 324). The second metal may define a set of electrodes 326, 328, 330, 332, 334, 336, 338, 340 that electrically connect the array of resistor pixels 306, 308, 310, 312 and the set of conductive pads 314, 316, 318, 320, 322, 324 in a full Wheatstone bridge. The second metal may alternatively be gold, copper, aluminum, or another type of metal. In some embodiments, and as shown, each electrode 326, 328, 330, 332, 334, 336, 338, 340 may extend from at or about a conductive pad 314, 316, 318, 320, 322, 324, to a resistor pixel 306, 308, 310, 312, to past the resistor pixel 306, 308, 310, 312 (i.e., past the side of the resistor pixel 306, 308, 310, 312) that is opposite the conductive pad 314, 316, 318, 320, 322, 324, and toward an adjacent resistor pixel 306, 308, 310, 312. Closer proximity of the electrodes coupled to different half bridges of the full Wheatstone bridge can help distribute temperature changes across different resistor pixels 306, 308, 310, 312.

As shown in FIG. 3B, a protective coating 342 may encapsulate the strain sensor 302 between the flexible printed circuit 304 and the protective coating 342.

In some embodiments, the resistor pixels 306, 308, 310, 312 may be electrically connected such that the voltage across the terminals N and P is proportional to:

$$[ \frac{R\_STG3}{R\_STG3 + R\_STG1} - \frac{R\_STG2}{R\_STG2 + R\_STG4} ]$$

FIG. 4 shows an example plan view of a strain-sensing device 400 including a second strain sensor 402. The strain sensor 402 is an example of any of the strain sensing pixels described with reference to FIGS. 2A-2D.

The strain sensor 402 may be formed on a flexible printed circuit 404 or other substrate. The strain sensor 402 may include a conductive ink (e.g., a carbon fiber ink) that is printed on the flexible printed circuit 404. The conductive ink may have a resistance and define an array of resistor pixels 406, 408 having an array width (WA) and an array length (LA). By way of example, the strain sensor 402 has two resistor pixels 406, 408, which resistor pixels 406, 408 may be electrically coupled to one another in a half Wheatstone bridge.

Each resistor pixel 406, 408 is shown to have the same dimensions and be positioned in a different location of a grid formation. In alternative embodiments, resistor pixels may have different sizes or different placements. When the resistor pixels 406, 408 have the same dimensions, each resistor pixel 406, 408 may have a pixel width (WP) along the array width (WA) and a pixel length (LP) along the array length (LA). Along the array length, the resistor pixels 406, 408 may have an edge-to-edge spacing (LS; between a resistor pixel and an adjacent resistor pixel).

Because temperature can change the resistance of one or more resistor pixels, and to reduce the effects of temperature on strain sensing, the resistor pixels 406, 408 may be positioned relatively closer to one another (i.e., so that the resistor pixels 406, 408 experience similar temperature changes and one resistor pixel does not become much warmer or cooler than the other resistor pixels). However, positioning the resistor pixels 406, 408 too close to each other can reduce a strain sensor's sensitivity to strain. In some embodiments, the edge-to-edge spacing may be less than or equal to two times the pixel length, to minimize the impact of temperature differentials between the resistor pixels 406, 408. In some embodiments, the edge-to-edge spacing may be between one and two times the pixel length. In some embodiments, the edge-to-edge spacing may be less than or equal to the pixel length.

A first metal (e.g., copper) may be printed on the flexible printed circuit 404 and define a set of conductive pads 410, 412, 414. The conductive pads 410, 412, 414 may be positioned close to the resistor pixels 406, 408 (e.g., within two times the pixel width, or between one and two times the pixel width, or within one pixel width), so that they tend to response to temperature changes similarly to the resistor pixels 406, 408. Although copper is a good thermal conductor, the first metal could alternatively be silver, gold, aluminum, or another type of metal. One of the conductive pads 412 may be shared by the resistor pixels 406, 408 and help distribute temperature changes across the resistor pixels 406, 408. In some embodiments, and as shown, the conductive pad 412 may overlap the lengths of the resistor pixels 406, 408. The overlap may amount to up to 25% of the pixel length (or up to 50%, or up to 75%, or more).

A second metal (e.g., silver) may be printed at least partially on the flexible printed circuit 404 (and at least partially on the resistor pixels 406, 408 and conductive pads 410, 412, 414). The second metal may define a set of electrodes 416, 418, 420, 422 that electrically connect the array of resistor pixels 406, 408 and the set of conductive pads 410, 412, 414 in a half Wheatstone bridge. The second metal may alternatively be gold, copper, aluminum, or another type of metal.

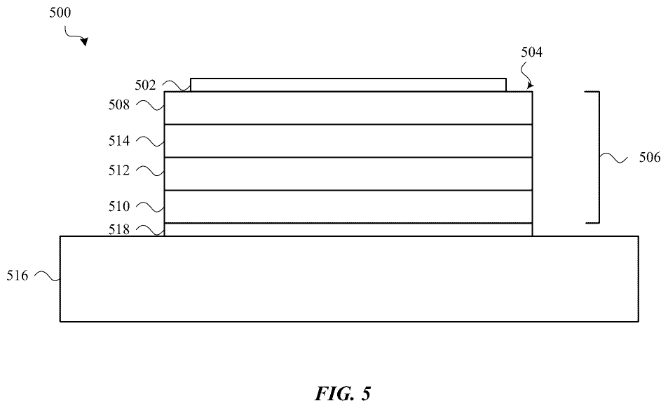

FIG. 5 shows an example elevation of a strain-sensing device 500 including a strain sensor 502 formed on a flexible printed circuit 504. In some embodiments, the components of the strain sensor 502 may be printed on the flexible printed circuit 504, as described with reference to FIGS. 3A, 3B, and 4. In some embodiments, the strain sensor 502 may be any of the strain sensors described with reference to FIG. 2A-2D, 3A-3B, or 4.

The flexible printed circuit 504 may include a stacked set of layers 506. In some embodiments, the stacked set of layers 506 may include a first polyimide layer 508, a second polyimide layer 510, and an adhesive layer 512 disposed between the first polyimide layer 508 and the second polyimide layer 510. In some embodiments, the adhesive layer 512 may include a polymeric adhesive. Optionally, the stacked set of layers 506 may include a metallic shield layer 514 disposed between the first polyimide layer 508 and the adhesive layer 512. In some embodiments, the metallic shield layer 514 may include copper. In alternative embodiments, the polyimide layers may alternatively be polyester layers (e.g., Polyethylene terephthalate (PET) layers) or other plastic layers and/or the metallic shield layer 514 may include aluminum or another type of conductor or metal.

The flexible printed circuit 504 of the strain-sensing device 500 may be attached to a substrate 516 (e.g., a component including a surface) that directly or indirectly receives an applied force (e.g., a user input force) and undergoes strain as a result of the applied force. In some embodiments, the substrate 516 to which the flexible printed circuit 504 is attached may be the bracket or user input member described with reference to FIGS. 2A-2D. In some embodiments, the substrate 516 may include stainless steel. In some embodiments, the second polyimide layer 510 of the flexible printed circuit 504 may be attached to the substrate 516 by an adhesive 518 (e.g., an epoxy). Strain experienced by the substrate 516 as a result of the applied force may propagate through the flexible printed circuit 504 and be sensed by the strain sensor 502.

Depending on their materials, changes in temperature can affect the glass transition temperature (Tg) and shear modulus of each layer in the stacked set of layers 506. As a result, it may be desirable to select materials that have a Tg (e.g., at atmospheric pressure) that is greater than the expected operating temperature range of the strain-sensing device 500, and preferably much greater (e.g., at least 10% greater, at least 25% greater, or more). In embodiments in which the strain-sensing device is used on a button of a consumer electronics device (e.g., a smartphone, electronic watch, game controller, etc.), each layer in the stacked set of layers 506 may be chosen to have a Tg greater than 50 degrees Celsius (50° C.). In addition, each pair of adjacent layers in the stacked set of layers 506 may have a Tg greater than 50° C., and the entire set of stacked layers 506 may have a Tg greater than 50° C.

In some cases, two adjacent materials, each having a Tg greater than the high temperature of an operating temperature range, may be altered, when bonded to each other, such that their combined Tg is lower than the Tg of one or both of the materials. Thus, it may be insufficient to simply select stack materials that have a high enough Tg in isolation; and instead, the Tg of each bilayer, or of the entire stack, may need to be analyzed or measured.

To ensure that all or a substantial majority of the strain experienced by the substrate 516 is transferred to the strain sensor 502, the Tg of each flexible printed circuit layer, and the set of stacked layers 506 as a whole, should remain greater than the expected operating temperature range of the strain-sensing device 500. In the example provided herein, 50° C. is a sufficient high end temperature to encompass an expected operating temperature range. In other examples or applications, a different temperature (lower or higher) may be used as the high end temperature of an expected operating temperature range.

As an example, and in some embodiments, a first layer in the stacked set of layers 506 (e.g., the adhesive layer 512) may have a Tg greater than 70° C.; a second layer in the stacked set of layers 506 (e.g., the second polyimide layer 510), adjacent the first layer, may have a Tg greater than 50° C.; and the first and second layers, when bonded, may have a Tg greater than 50° C.

As another example, and in some embodiments, a first layer in the stacked set of layers 506 may have a Tg greater than 70° C.; a second layer in the stacked set of layers 506, adjacent the first layer, may have a Tg greater than 70° C.; and the first and second layers, when bonded, may have a Tg greater than 50° C.

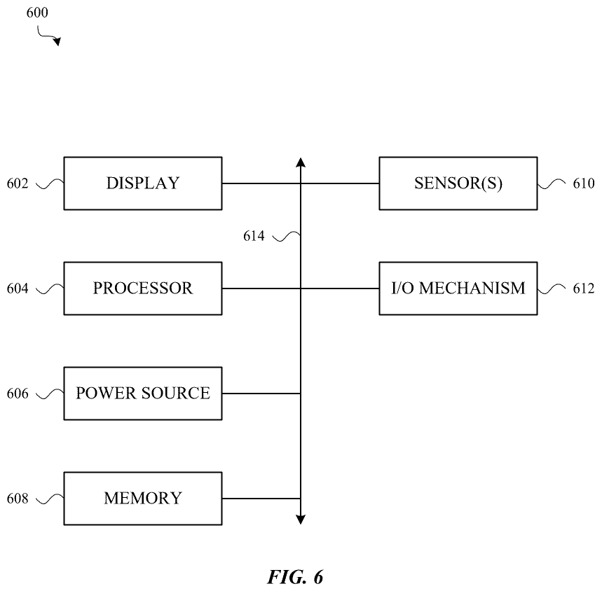

FIG. 6 shows an example electrical block diagram of an electronic device 600, which electronic device 600 may in some cases be the electronic device described with reference to FIGS. 1A and 1B, and which electronic device 600 may include a user input assembly as described with FIGS. 2A-2D and a strain-sensing device as described with reference to FIGS. 2A-5. The electronic device 600 may optionally include an electronic display 602 (e.g., a light-emitting display), a processor 604, a power source 606, a memory 608 or storage device, a sensor system 610, and/or an input/output (I/O) mechanism 612.

The processor 604 may control some or all of the operations of the electronic device 600. The processor 604 may communicate, either directly or indirectly, with some or all of the other components of the electronic device 600. For example, a system bus or other communication mechanism 614 can provide communication between the electronic display 602, the processor 604, the power source 606, the memory 608, the sensor system 610, and the I/O mechanism 612.

The processor 604 may be implemented as any electronic device capable of processing, receiving, or transmitting data or instructions, whether such data or instructions are in the form of software or firmware or otherwise encoded. The processor 604 may also receive, transmit, or cause other circuits to transmit control signals. As examples, the processor 604 may include a microprocessor, a central processing unit (CPU), an application-specific integrated circuit (ASIC), a digital signal processor (DSP), a control circuit, or a combination of such devices. As described herein, the term “processor” is meant to encompass a single processor or processing unit, multiple processors or processing units, or other suitably configured computing element or elements. In some cases, the processor 604 may be a distributed processor.

It should be noted that the components of the electronic device 600 can be controlled by multiple processors. For example, select components of the electronic device 600 (e.g., the sensor system 610) may be controlled by a first processor, and other components of the electronic device 600 (e.g., the electronic display 602) may be controlled by a second processor, where the first and second processors may or may not be in communication with each other.

The power source 606 can be implemented with any device capable of providing energy to the electronic device 600. For example, the power source 606 may include one or more batteries or rechargeable batteries. Additionally, or alternatively, the power source 606 may include a power connector or power cord that connects the electronic device 600 to another power source, such as a wall outlet. Additionally, or alternatively, the power source 606 may include a battery in combination with a wireless charging interface.

The memory 608 may store electronic data that can be used by the electronic device 600. For example, the memory 608 may store electrical data or content such as, for example, audio and video files, documents and applications, device settings and user preferences, timing signals, control signals, instructions, and/or data structures or databases. The memory 608 may include any type of memory. By way of example only, the memory 608 may include random access memory, read-only memory, Flash memory, removable memory, other types of storage elements, or combinations of such memory types.

The electronic device 600 may also include one or more sensor systems 610 positioned almost anywhere on the electronic device 600. In some cases, the sensor systems 610 may include one or more of the strain-sensing devices or strain sensors described with reference to FIGS. 1A-5. The sensor system(s) 610 may be configured to sense one or more types of parameters, such as but not limited to, vibration; light; touch; force; heat; strain; movement; relative motion; biometric data (e.g., biological parameters) of a user; air quality; proximity; position; connectedness; surface quality; and so on. By way of example, the sensor system(s) 610 may include a heat sensor, a position sensor, a light or optical sensor, an accelerometer, a pressure transducer, a gyroscope, a magnetometer, a health monitoring sensor, an air quality sensor, a strain sensor, and so on. Additionally, the one or more sensor systems 610 may utilize any suitable sensing technology, including, but not limited to, interferometric, magnetic, capacitive, ultrasonic, resistive, optical, acoustic, piezoelectric, or thermal technologies.

The I/O mechanism 612 may transmit or receive data from a user or another electronic device. The I/O mechanism 612 may include the electronic display 602, a touch sensing input surface, a crown, one or more buttons (e.g., a graphical user interface “home” button), one or more cameras (including an under-display camera), one or more microphones or speakers, one or more ports such as a microphone port, and/or a keyboard. Additionally, or alternatively, the I/O mechanism 612 may transmit electronic signals via a communications interface, such as a wireless, wired, and/or optical communications interface. Examples of wireless and wired communications interfaces include, but are not limited to, cellular and Wi-Fi communications interfaces. In some embodiments, the I/O mechanism 612 may include aspects that are integrated with the sensor system 610 or the electronic display 602.

The foregoing description, for purposes of explanation, uses specific nomenclature to provide a thorough understanding of the described embodiments. However, it will be apparent to one skilled in the art, after reading this description, that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art, after reading this description, that many modifications and variations are possible in view of the above teachings.

What is claimed is:

1. An electronic device, comprising:
a housing;
a bracket disposed interior to the housing and coupled to the housing;
a user input member coupled to and movable with respect to the housing, the user input member having a user input surface exterior to the housing and an actuation surface interior to the housing;
a tactile switch actuated by movement of the actuation surface toward the bracket, the tactile switch providing a first haptic output to the user input member when an amount of force applied to the user input surface satisfies an actuation force of the tactile switch;
a strain sensor laminated to the bracket or to the user input member, the strain sensor positioned to experience strain as a force is applied to the user input surface;
a haptic actuator coupled to the user input member and providing a second haptic output to the user input member when the haptic actuator is triggered; and
a control circuit configured to receive an output of the strain sensor, the control circuit triggering the haptic actuator when the output of the strain sensor indicates the amount of force applied to the user input surface satisfies a force threshold that is less than an amount of force required to satisfy the actuation force of the tactile switch.

2. The electronic device of claim 1, further comprising:
a flexible printed circuit; wherein,
the strain sensor is printed on the flexible printed circuit; and
the flexible printed circuit is laminated to the bracket.

3. The electronic device of claim 2, wherein the strain sensor comprises at least a first strain sensing pixel and a second strain sensing pixel on the flexible printed circuit.

4. The electronic device of claim 1, further comprising:
a flexible printed circuit; wherein,
the strain sensor is printed on the flexible printed circuit; and
the flexible printed circuit is laminated to the user input member.

5. The electronic device of claim 4, wherein the strain sensor comprises at least a first strain sensing pixel and a second strain sensing pixel on the flexible printed circuit.

6. The electronic device of claim 1, wherein:
the housing is a smartphone housing; and
the user input member is a button.

7. A strain-sensing device, comprising:
a flexible printed circuit comprising a stacked set of layers, each layer in the stacked set of layers having a glass transition temperature (Tg) greater than 50 degrees Celsius (50° C.), and each pair of adjacent layers in the stacked set of layers having a Tg greater than 50° C.; and
a strain sensor formed on the flexible printed circuit.

8. The strain-sensing device of claim 7, wherein:
the stacked set of layers includes,
a first polyimide layer;
a second polyimide layer; and
an adhesive layer disposed between the first polyimide layer and the second polyimide layer.

9. The strain-sensing device of claim 8, wherein the stacked set of layers includes a metallic shield layer disposed between the first polyimide layer and the adhesive layer.

10. The strain-sensing device of claim 9, wherein the metallic shield layer comprises copper.

11. The strain-sensing device of claim 9, further comprising:
a substrate configured to directly or indirectly receive a user input force; and
an epoxy attaching the second polyimide layer to the substrate; wherein,
the strain sensor senses a strain experienced by the substrate as a result of the user input force.

12. The strain-sensing device of claim 11, wherein the substrate comprises stainless steel.

13. The strain-sensing device of claim 8, wherein:
a first layer in the stacked set of layers has a Tg greater than 70° C.; and
a second layer in the stacked set of layers, adjacent the first layer, has a Tg greater than 50° C.

14. The strain-sensing device of claim 13, wherein:
the first layer is the adhesive layer; and
the second layer is the second polyimide layer.

15. The strain-sensing device of claim 7, wherein the strain sensor comprises a carbon fiber ink printed on the flexible printed circuit.

16. A strain-sensing device, comprising:
a flexible printed circuit;
a conductive ink on the flexible printed circuit and defining an array of resistor pixels, the array of resistor pixels having an array width and an array length, wherein,
for a resistor pixel in the array of resistor pixels, the resistor pixel has,
a pixel width along the array width;
a pixel length along the array length; and
an edge-to-edge spacing between the resistor pixel and an adjacent resistor pixel, along the array length, that is less than or equal to two times the pixel length;
a first metal on the flexible printed circuit and defining a set of conductive pads; and
a second metal at least partially on the flexible printed circuit and electrically connecting the array of resistor pixels and the set of conductive pads in one of a half Wheatstone bridge or a full Wheatstone bridge.

17. The strain-sensing device of claim 16, wherein the edge-to-edge spacing between the resistor pixel and the adjacent resistor pixel is between one and two times the pixel length.

18. The strain-sensing device of claim 16, wherein the edge-to-edge spacing between the resistor pixel and the adjacent resistor pixel is less than or equal to the pixel length.

19. The strain-sensing device of claim 16, wherein:
the adjacent resistor pixel is a first adjacent resistor pixel;
the edge-to-edge spacing is a first edge-to-edge spacing; and
for the resistor pixel in the array of resistor pixels, the resistor pixel has a second edge-to-edge spacing between the resistor pixel and a second adjacent resistor pixel, along the array width, that is less than or equal to two times the pixel width.

20. The strain-sensing device of claim 19, wherein the second edge-to-edge spacing between the resistor pixel and the second adjacent resistor pixel is between one and two times the pixel width.
